(19) United States
(12) Patent Application Publication
(10) Pub. No.: US 2025/0100870 A1
(43) Pub. Date: Mar. 27, 2025

(54) Controller for sound producing device with dynamic vent function

(71) Applicant: xMEMS Labs, Inc., Santa Clara, CA (US)

(72) Inventors: Ming-Hung Chang, Hsinchu County (TW); Chiung C. Lo, San Jose, CA (US)

(73) Assignee: xMEMS Labs, Inc., Santa Clara, CA (US)

(21) Appl. No.: 18/977,823

(22) Filed: Dec. 11, 2024

Related U.S. Application Data
(63) Continuation-in-part of application No. 17/955,562, filed on Sep. 29, 2022.
Application No. 17/955,562 is a division of application No. 17/842,810, filed on Jun. 17, 2022, now Pat. No. 11,884,535.
Application No. 17/842,810 is a continuation-in-part of application No. 17/344,980, filed on Jun. 11, 2021, now Pat. No. 11,399,228.
(60) Provisional application No. 63/050,763, filed on Jul. 11, 2020.
(60) Provisional application No. 63/051,885, filed on Jul. 14, 2020.
(60) Provisional application No. 63/171,919, filed on Apr. 7, 2021.
(60) Provisional application No. 63/320,703, filed on Mar. 17, 2022.
(60) Provisional application No. 63/609,881, filed on Dec. 14, 2023.

(51) Int. Cl. B81B 3/00; H04R 31/00

(52) U.S. Cl. CPC B81B 3/0021; B81B 3/0051; B81B 3/0072; H04R 31/00; B81B 2201/0257; B81B 2203/0127; B81B 2203/0163; B81B 2207/03

(57) ABSTRACT

A controller for controlling a sound producing device includes a vent controller and an audio amplifier. The vent controller is configured to output a first driving voltage and a second driving voltage to the sound producing device, to control the sound producing device to form a vent. The audio amplifier is configured to output a first audio signal to the sound producing device, to produce a sound. The sound producing device comprises a flap pair, and the flap pair comprises a first flap and a second flap. The vent controller outputs the first driving voltage and actuates the first flap to generate a first displacement, the vent controller outputs the second driving voltage and actuates the second flap to generate a second displacement, and the vent is formed because of a difference between the first displacement and the second displacement.

### CROSS REFERENCE TO RELATED APPLICATIONS

This application is a continuation-in-part of U.S. application Ser. No. 17/955,562, filed on Sep. 29, 2022, which is a division of U.S. application Ser. No. 17/842,810, filed on Jun. 17, 2022, which is a continuation-in-part of U.S. application Ser. No. 17/344,980, filed on Jun. 11, 2021, which claims the benefit of U.S. Provisional Application No. 63/050,763, filed on Jul. 11, 2020, and claims the benefit of U.S. Provisional Application No. 63/051,885, filed on Jul. 14, 2020, and claims the benefit of U.S. Provisional Application No. 63/171,919, filed on Apr. 7, 2021. Besides, U.S. application Ser. No. 17/842,810 claims the benefit of U.S. Provisional Application No. 63/320,703, filed on Mar. 17, 2022. Further, this application claims the benefit of U.S. Provisional Application No. 63/609,881, filed on Dec. 14, 2023. The contents of these applications are incorporated herein by reference.

### BACKGROUND OF THE INVENTION

### 1. Field of the Invention

The present invention relates to a controller, and more particularly, to a controller capable of controlling a sound producing device to form a vent.

### 2. Description of the Prior Art

Unless otherwise indicated herein, the approaches described in this section are not prior art to the claims in this application and are not admitted as prior art by inclusion in this section.

Nowadays, wearable sound devices, such as in-ear (insert into ear canal) earbuds, on-ear or over-ear earphones, are generally used for producing sound or receiving sound. Magnet and moving coil (MMC) based micro speakers have been developed for decades and widely used in many such devices. Recently, MEMS (Micro Electro Mechanical System) acoustic transducers which make use of a semiconductor fabrication process can be sound producing/receiving components in the wearable sound devices.

In order to reduce the occlusion effect, U.S. application Ser. No. 17/955,562 has provided a method of driving a flap pair to move in an appropriate manner to form a dynamic vent therebetween, where each flap may serve as a portion of membrane. The driving voltages that used to drive the flap pair to form the vent are direct current (DC) voltages, while the membrane is requested to be driven through alternating current (AC) voltages to produce sound.

### SUMMARY OF THE INVENTION

It is therefore an objective of the present invention to provide a controller which is capable of driving a sound producing device with a driving signal having DC component and AC component, so as to control the flap pair of the sound producing device to form a vent and also drive the sound producing device to produce sound.

An embodiment of the present invention discloses a controller for controlling a sound producing device. The controller comprises a vent controller and an audio amplifier. The vent controller is configured to output a first driving voltage and a second driving voltage to the sound producing device, to control the sound producing device to form a vent. The audio amplifier is configured to output a first audio signal to the sound producing device, to produce a sound. The sound producing device comprises a flap pair, and the flap pair comprises a first flap and a second flap. The vent controller outputs the first driving voltage and actuates the first flap to generate a first displacement, the vent controller outputs the second driving voltage and actuates the second flap to generate a second displacement, and the vent is formed because of a difference between the first displacement and the second displacement.

Another embodiment of the present invention discloses a controller for controlling a sound producing device. The controller comprises an audio amplifier, which is configured to drive the sound producing device to form a vent and to produce a sound. The sound producing device comprises a flap pair, and the flap pair comprises a first flap and a second flap. The audio amplifier actuates the first flap to generate a first displacement, the audio amplifier actuates the second flap to generate a second displacement, and the vent is formed because of a difference between the first displacement and the second displacement.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an audio control system according to an embodiment of the present invention.

FIGS. 2A-2C illustrate several states of the vent formed by a flap pair.

FIG. 3 is a schematic diagram of a detailed implementation of the audio control system.

FIG. 4 is a schematic diagram of another detailed implementation of the audio control system.

FIG. 5 is a schematic diagram of a detailed implementation of the audio control system with the feedback mechanism.

FIG. 6 is a schematic diagram of another detailed implementation of the audio control system with the feedback mechanism.

FIG. 7 is a schematic diagram of a detailed implementation of the audio control system with a direct drive scheme.

FIG. 8 is a schematic diagram of another detailed implementation of the audio control system with the direct drive scheme.

### DETAILED DESCRIPTION

To provide a better understanding of the present invention to those skilled in the art, preferred embodiments and typical material or range parameters for key components will be detailed in the following description. These preferred embodiments of the present invention are illustrated in the accompanying drawings with numbered elements to elaborate on the contents and effects to be achieved. It should be noted that the drawings are simplified schematics, and the material and parameter ranges of key components are illustrative based on the present day technology, and therefore show only the components and combinations associated with the present invention, so as to provide a clearer description for the basic structure, implementing or operation method of the present invention. The components would be more complex in reality and the ranges of parameters or material used may evolve as technology progresses in the future. In addition, for ease of explanation, the components shown in the drawings may not represent their actual number, shape, and dimensions; details may be adjusted according to design requirements.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present invention, the corresponding features, areas, steps, operations and/or components would be pointed to existence, but not limited to the existence of one or a plurality of the corresponding features, areas, steps, operations and/or components.

In the following description and in the claims, when “a A1 component is formed by/of B1”, B1 exist in the formation of A1 component or B1 is used in the formation of A1 component, and the existence and use of one or a plurality of other features, areas, steps, operations and/or components are not excluded in the formation of A1 component.

Although terms such as first, second, third, etc., may be used to describe diverse constituent elements, such constituent elements are not limited by the terms. The terms are used only to discriminate a constituent element from other constituent elements in the specification, and the terms do not relate to the sequence of the manufacture if the specification does not describe. The claims may not use the same terms, but instead may use the terms first, second, third, etc. with respect to the order in which an element is claimed. Accordingly, in the following description, a first constituent element may be a second constituent element in a claim.

It should be noted that the technical features in different embodiments described in the following can be replaced, recombined, or mixed with one another to constitute another embodiment without departing from the spirit of the present invention.

Contents of U.S. Pat. Nos. 11,399,228, 11,323,797 and descendant applications thereof are incorporated herein by reference.

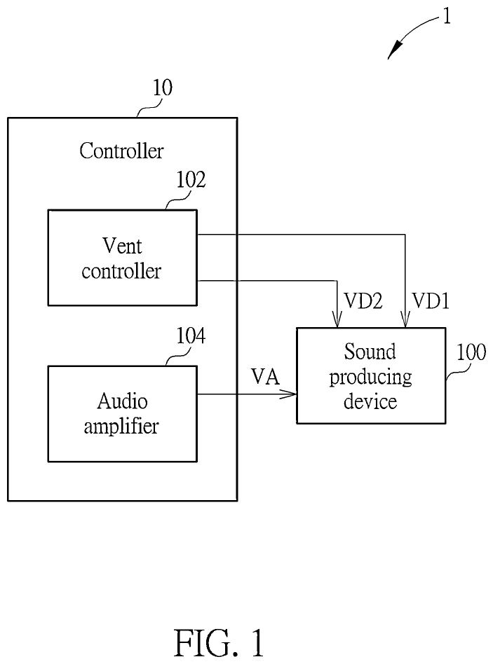

FIG. 1 is a schematic diagram of an audio control system 1 according to an embodiment of the present invention. The audio control system 1 includes a controller 10 and a sound producing device 100 which is controlled by the controller 10. The sound producing device 100 may include a membrane for producing sound, which is implemented with a flap pair actuated appropriately to form the vent. U.S. application Ser. No. 17/955,562 discloses several exemplary implementations of the flap pair, which are not repeated herein for brevity.

The sound producing device 100 may convert electric signals or any other suitable signals to an acoustic wave. In various embodiments, the sound producing device 100 may be implemented in an acoustic transducer, and/or may be a speaker, micro speaker, or any other suitable device, but not limited thereto.

The controller 10 includes a vent controller 102 and an audio amplifier 104. The vent controller 102 is configured to control the operations of the flap pair included in the sound producing device 100 by outputting driving voltages VD1 and VD2. In various embodiments, the driving voltages VD1 and VD2 may be DC voltages capable of actuating the corresponding flaps to move to a target position. The audio amplifier 104 is configured to provide an audio signal VA to the sound producing device 100. The audio signal VA may drive the membrane of the sound producing device 100 to vibrate and produce desired sounds. In various embodiments, the audio signal VA may be an AC voltage, e.g., a sinewave signal with a specific amplitude and frequency. This AC voltage may be combined with (e.g., carried on) the DC driving voltages VD1 and VD2 to be received by the sound producing device 100. Therefore, the flap pair of the sound producing device 100 may form a vent with various states and also possess sound producing functions.

In various embodiments, the flap pair may include a first flap and a second flap, which are controlled by the driving voltages VD1 and VD2, respectively. The driving voltage VD1 may actuate the first flap to generate a first displacement, and the driving voltage VD2 may actuate the second flap to generate a second displacement. The difference between the first displacement and the second displacement may form the vent and determine the state of the vent.

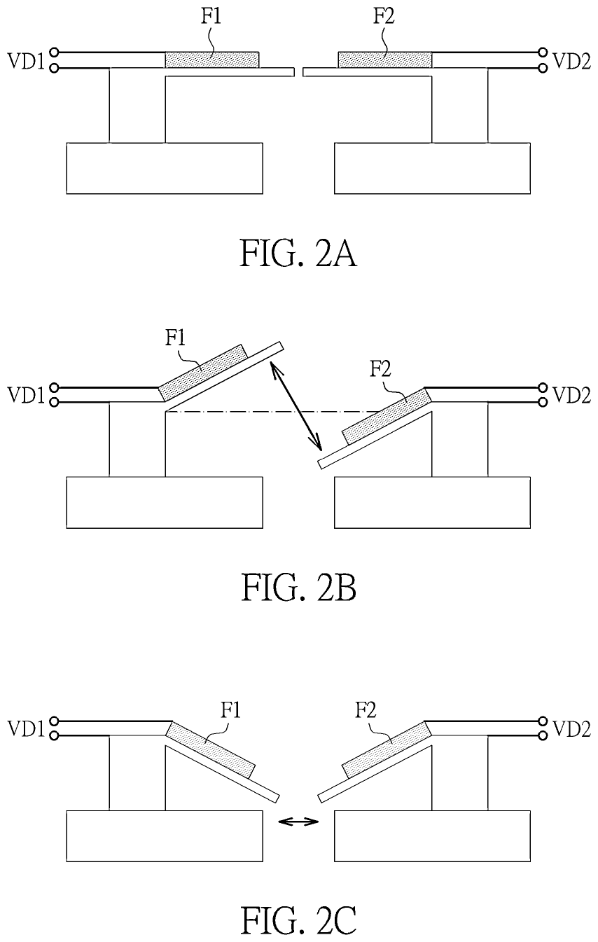

FIGS. 2A-2C illustrate several states of the vent formed by a flap pair, which is composed of a first flap F1 and a second flap F2. The flap pair may be actuated to be in different states under different applications.

In detail, FIG. 2A illustrates a vent seal state, where the vent is extremely small to isolate ambient sounds/noises and maximize the listening experience. The vent seal state may be realized by controlling the driving voltages VD1 and VD2 to be at a medium level (e.g., 15V).

FIG. 2B illustrates a vent open state. Note that the occlusion effect may appear when the vent is extremely small, such as the case shown in FIG. 2A. This problem may be solved by driving the first flap F1 and the second flap F2 to move toward opposite directions, to make the vent larger to release the occlusion pressure. The vent open state may be realized by controlling the driving voltages VD1 and VD2 to be at different levels. For example, the driving voltage VD1 may be at a high level (e.g., 30V) and the driving voltage VD2 may be at a low level (e.g., 0V) to achieve the open vent.

FIG. 2C illustrates a vent close state, where the vent has a small opening. This state is suitable for long-term wearing of an earphone or earbud. The vent close state may be realized by controlling the driving voltages VD1 and VD2 to be at the same level. For example, the driving voltages VD1 and VD2 may both be at a low level (e.g., 0V) to achieve the closed vent. In another embodiment, the vent close state may be realized when the driving voltages VD1 and VD2 are floating.

As can be seen, the driving voltages VD1 and VD2 may be DC voltages which control the displacement of the first flap F1 and/or the second flap F2, where the displacement may be greater than the thickness of the flap pair. In comparison, the audio signal VA may be a small voltage variation (i.e., AC voltage) carried on the DC driving voltages VD1 and VD2, to generate a small vibration (e.g., with a movement/displacement smaller than the thickness of the flap pair) on the membrane of the flap pair.

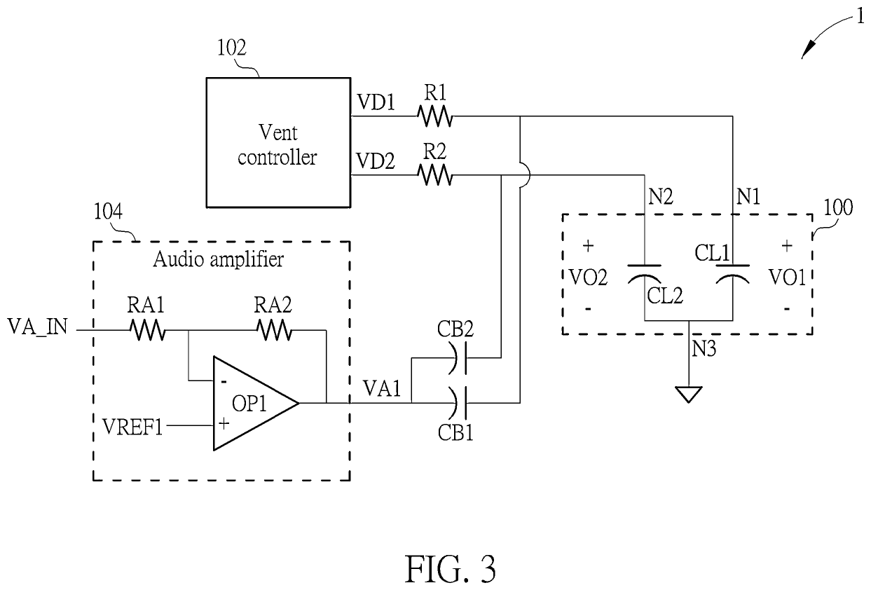

FIG. 3 is a schematic diagram of a detailed implementation of the audio control system 1. As shown in FIG. 3, the sound producing device 100 may be regarded as a capacitive load, which is modeled by two capacitors CL1 and CL2, where the capacitor CL1 is used to model the first flap and the capacitor CL2 is used to model the second flap. The sound producing device 100 may be a three-terminal device composed of the first flap and the second flap, where the first flap (modeled by CL1) is coupled between the nodes N1 and N3, and the second flap (modeled by CL2) is coupled between the nodes N2 and N3. In other words, the node N1 may be regarded as the first terminal of the first flap (which may be corresponding to top electrode of first actuator (not shown in FIG. 3) disposed on the first flap), the node N2 may be regarded as the first terminal of the second flap (which may be corresponding to top electrode of second actuator (not shown in FIG. 3) disposed on the second flap), and the node N3 may be regarded as the second terminal of the first flap (which may be corresponding to bottom electrode of the first actuator) and also regarded as the second terminal of the second flap (which may be corresponding to bottom electrode of the second actuator), where the second terminal of the first flap may be connected to the second terminal of the second flap.

Details of the arrangement of the flaps, the actuators and the electrodes may be referred to U.S. Pat. Nos. 11,399,228 and 11,323,797, which are not narrated herein for brevity.

In this embodiment, the audio control system 1 is operated in a single-ended mode, where the first terminal of the first flap and the second flap (i.e., N1 and N2) receives a driving voltage and audio signal, and the second terminal of the first flap and the second flap (i.e., N3) is coupled to ground.

As shown in FIG. 3, the vent controller 102 may be implemented as a voltage generator or bias generator, for generating and outputting the DC driving voltages VD1 and VD2. The audio control system 1 may further include two resistors R1 and R2 and two coupling capacitors CB1 and CB2. The resistor R1 is coupled between a first output terminal of the vent controller 102 and the first flap, to forward the driving voltage VD1 to the first flap. The resistor R2 is coupled between a second output terminal of the vent controller 102 and the second flap, to forward the driving voltage VD2 to the second flap. The coupling capacitor CB1 is coupled between an output terminal of the audio amplifier 104 and the first flap, and the coupling capacitor CB2 is coupled between the output terminal of the audio amplifier 104 and the second flap. Therefore, the audio signal VA1 may be coupled to the first flap through the coupling capacitor CB1 and may also be coupled to the second flap through the coupling capacitor CB2. In such a situation, the AC audio signal VA1 may be combined with the DC driving voltage VD1 on the node N1 to be received by the first flap, and may also be combined with the DC driving voltage VD2 on the node N2 to be received by the second flap. Therefore, the operating voltages VO1 and VO2 of the sound producing device 100 may be obtained as follows:

$$\begin{matrix}VO 1 = VD 1 + VA 1 ; \\ VO 2 = VD 2 + VA 1.\end{matrix}$$

Details of the vent controller 102 may be realized according to the teaching of U.S. Pat. No. 12,028,673, which are not narrated herein for brevity.

The audio amplifier 104 is configured to amplify an audio input signal VA_IN to generate the audio signal VA1 and output the audio signal VA1 to the first flap and the second flap of the sound producing device 100. As mentioned above, the audio control system 1 is operated in the single-ended mode, and thus the audio amplifier 104 may be or comprise a single-ended amplifier, which receive one audio input signal (i.e., VA_IN) to output one audio signal (i.e., VA1). In detail, the audio amplifier 104 includes an operational amplifier (op-amp) OP1 and two resistors RA1 and RA2. The resistor RA1 is coupled between the audio input terminal and the negative input terminal of the op-amp OP1. The resistor RA2 is coupled between the negative input terminal of the op-amp OP1 and the output terminal of the op-amp OP1. The audio input terminal is a terminal used to receive the audio input signal VA_IN. Therefore, the amplification ratio of the audio amplifier 104 may be well controlled by designing the values of the resistors RA1 and RA2 in a suitable manner. The positive input terminal of the op-amp OP1 may further receive a reference voltage VREF1, as a bias voltage for the audio signal VA1.

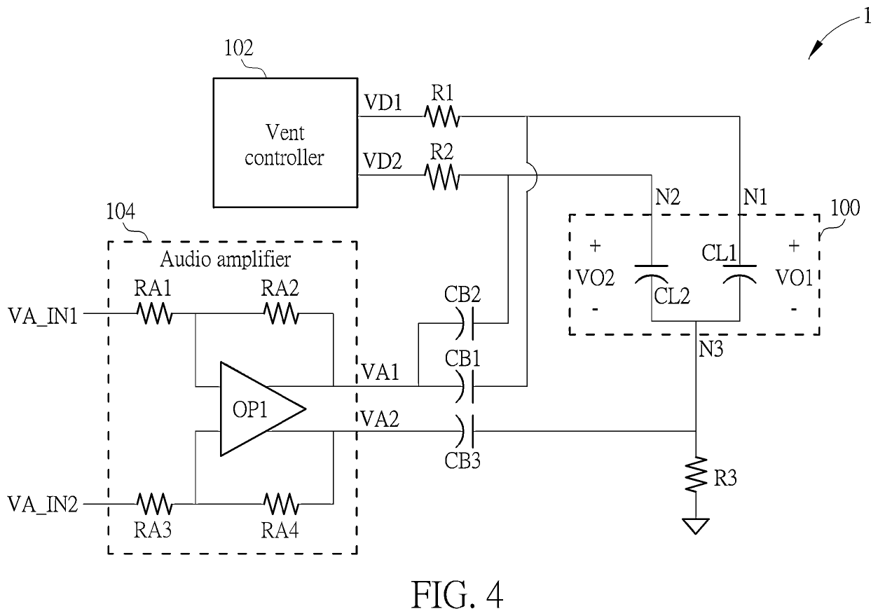

FIG. 4 is a schematic diagram of another detailed implementation of the audio control system 1. The circuit structure of the audio control system 1 shown in FIG. 4 is similar to that shown in FIG. 3, so signals and elements having similar functions are denoted by the same symbols. Their difference is that the audio control system 1 shown in FIG. 4 is operated in a differential mode, and thus the audio amplifier 104 is configured to receive a differential audio input signal to generate and output a differential audio signal to the sound producing device 100, and an additional coupling capacitor CB3 is included to be coupled between the node N3 and the audio amplifier 104.

In this embodiment, the audio amplifier 104 may be or comprise a differential amplifier, which receives audio input signals VA_IN1 and VA_IN2 as the differential audio input signal, and outputs audio signals VA1 and VA2 as the differential audio output signal. The audio signal VA1 may be coupled to the nodes N1 and N2 through the coupling capacitors CB1 and CB2, respectively, and the audio signal VA2 may be coupled to the node N3 through the coupling capacitor CB3. With the fully-differential audio signal VA1 and VA2, the sound producing device 100 may be provided with doubled audio signal amplitude. The operating voltages VO1 and VO2 of the sound producing device 100 may be obtained as follows:

$$\begin{matrix}VO 1 = VD 1 + ( VA 1 - VA 2 ) ; \\ VO 2 = VD 2 + ( VA 1 - VA 2 ) .\end{matrix}$$

As shown in FIG. 4, a resistor R3, which is coupled between the node N3 and the ground terminal, is used to provide a DC bias voltage for the negative terminal of the flap pair in the sound producing device 100. In another embodiment, the node N3 may be provided with the bias voltage in any suitable manner, which is not limited to the implementation shown in FIG. 4.

In detail, the differential amplifier may include an op-amp OP1 and four resistors RA1-RA4. The resistor RA1 is coupled between a first audio input terminal (for receiving the audio input signal VA_IN1) and a first input terminal of the op-amp OP1, the resistor RA2 is coupled between the first input terminal of the op-amp OP1 and a first output terminal of the op-amp OP1 (which is an output terminal for outputting the audio signal VA1), the resistor RA3 is coupled between a second audio input terminal (for receiving the audio input signal VA_IN2) and a second input terminal of the op-amp OP1, and the resistor RA4 is coupled between the second input terminal of the op-amp OP1 and a second output terminal of the op-amp OP1 (which is another output terminal for outputting the audio signal VA2).

The coupling capacitors CB1-CB3 are configured to isolate the sound producing device 100 from the DC bias voltage of the audio amplifier 104 while coupling the desired audio signals VA1 and VA2. In a preferable embodiment, the capacitance of each coupling capacitor CB1-CB3 is far greater than the capacitive load (i.e., the capacitors CL1 and CL2) of the sound producing device 100. Note that the capacitors CB1-CB3 and CL1-CL2 will generate a voltage/signal dividing effect when the audio signals VA1 and/or VA2 are coupled to the sound producing device 100 from the audio amplifier 104, and the coupling loss may be minimized if the capacitance of CB1-CB3 is far greater than CL1-CL2.

In other embodiments, a feedback mechanism is applied to control the audio amplifier, where the audio amplifier may receive a feedback signal from the sound producing device, to correct the output audio signal according to the feedback signal. The feedback mechanism may achieve a better linearity of the audio signal, thereby improving the sound quality.

For example, the sound producing device 100 may be a MEMS speaker, in which the capacitors CL1 and CL2 have the feature that their capacitance is variable when the voltage applied to the sound producing device 100 changes, e.g., when the voltage at the node N1 and/or N2 changes. The capacitance of CB1-CB3 may also be variable when the cross voltage of the coupling capacitor CB1-CB3 changes. In such a situation, the coupling ratio between CB1-CB3 and CL1-CL2 may be variable, resulting in that the audio signals actually coupled to the nodes N1 and N2 become nonlinear and have a distortion even if the audio signal VA1 output by the audio amplifier 104 is perfectly linear. The feedback mechanism allows the audio amplifier 104 to monitor the voltages/signals applied to the sound producing device 100 to detect the distortion of the voltages/signals. Based on the feedback signals, the audio amplifier 104 is able to recover the signal linearity to be received by the sound producing device 100 and improve the sound quality.

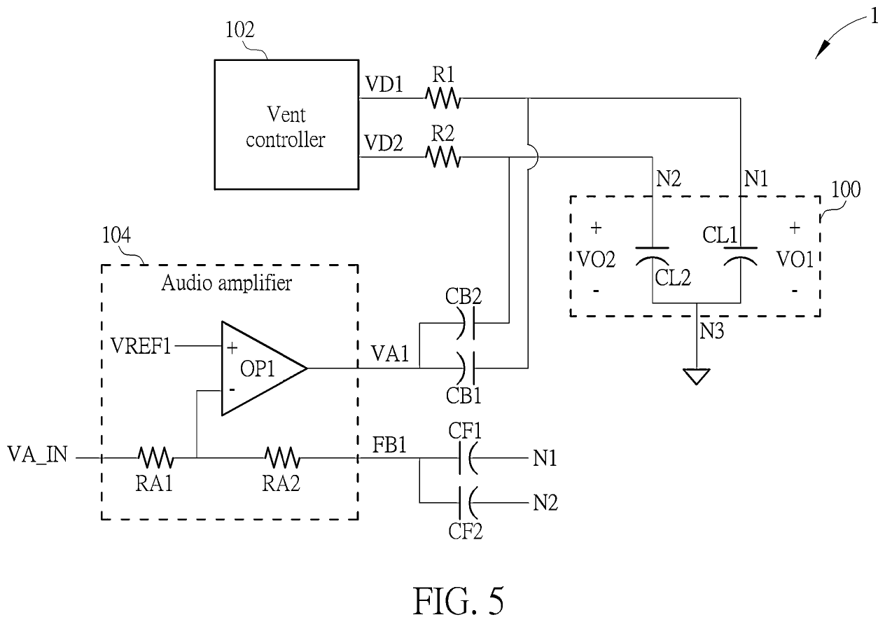

FIG. 5 is a schematic diagram of a detailed implementation of the audio control system 1 with the feedback mechanism. The circuit structure of the audio control system 1 shown in FIG. 5 is similar to that shown in FIG. 3, so signals and elements having similar functions are denoted by the same symbols. Their difference is that the audio control system 1 shown in FIG. 5 further includes two feedback capacitors CF1 and CF2 for the audio amplifier 104 to receive a feedback signal FB1 from the sound producing device 100. In detail, in addition to the output terminal for outputting the audio signal VA1, the audio amplifier 104 may further include a feedback terminal for receiving the feedback signal FB1. The feedback capacitor CF1 is coupled between the feedback terminal of the audio amplifier 104 and the node N1, and the feedback capacitor CF2 is coupled between the feedback terminal of the audio amplifier 104 and the node N2. Therefore, the feedback signal FB1 from the flap pair may be coupled to the audio amplifier 104 through the feedback capacitors CF1 and CF2.

With the feedback mechanism, the audio amplifier 104 may also be implemented differently. As shown in FIG. 5, the resistor RA2 in the audio amplifier 104 is coupled between the negative input terminal of the op-amp OP1 and the feedback terminal, rather than coupled to the output terminal of the op-amp OP1 or the output terminal of the audio amplifier 104. Other implementations of the audio amplifier 104 and the audio control system 1 are similar to the above embodiments without feedback control, and will not be repeated herein.

Based on the structure of the audio amplifier 104 and related negative feedback mechanism, the output audio signal VA1 may be adjusted based on the feedback signal FB1. For example, when determining that the feedback signal FB1 is too high, the audio amplifier 104 may decrease the audio signal VA1 to make the voltage at the node N1 and/or N2 reach its desired level; and when determining that the feedback signal FB1 is too low, the audio amplifier 104 may increase the audio signal VA1 to make the voltage at the node N1 and/or N2 reach its desired level.

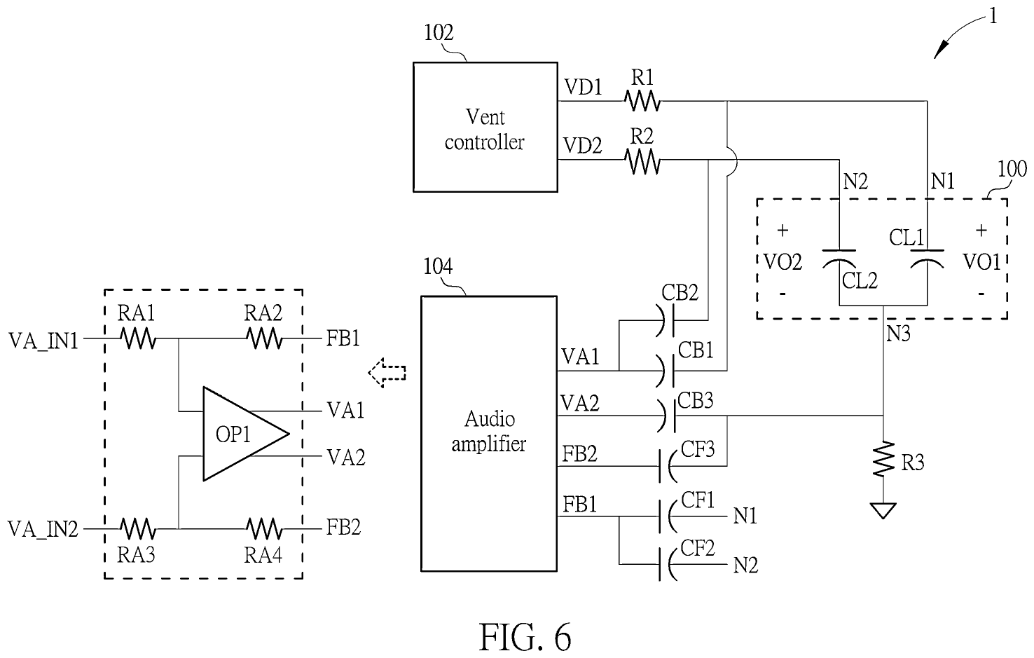

FIG. 6 is a schematic diagram of another detailed implementation of the audio control system 1 with the feedback mechanism. The circuit structure of the audio control system 1 shown in FIG. 6 is similar to that shown in FIG. 5, so signals and elements having similar functions are denoted by the same symbols. Their difference is that the audio control system 1 shown in FIG. 6 is operated in a differential mode, and thus the audio amplifier 104 is configured to receive a differential audio input signal VA_IN1 and VA_IN2 to generate and output a differential audio signal VA1 and VA2 to the sound producing device 100.

In this embodiment, the audio control system 1 includes coupling capacitors CB1-CB3 and feedback capacitors CF1-CF3. The implementations and operations of the coupling capacitors CB1-CB3 are similar to those shown in FIG. 4, and the implementations and operations of the feedback capacitors CF1-CF2 are similar to those shown in FIG. 5. With the feedback mechanism and differential implementation, the audio amplifier 104 may include another feedback terminal for receiving a feedback signal FB2 from the negative terminal of the flap pair in the sound producing device 100. Therefore, the audio control system 1 further includes a feedback capacitor CF3 coupled between this feedback terminal and the node N3, to couple the feedback signal FB2 from the flap pair to the audio amplifier 104.

The audio amplifier 104 may be designed accordingly to realize the feedback control under the differential mode. In detail, the differential amplifier may include an op-amp OP1 and four resistors RA1-RA4. The resistor RAI is coupled between a first audio input terminal (for receiving the audio input signal VA_IN1) and a first input terminal of the op-amp OP1, the resistor RA2 is coupled between the first input terminal of the op-amp OP1 and a first feedback terminal (for receiving the feedback signal FB1), the resistor RA3 is coupled between a second audio input terminal (for receiving the audio input signal VA_IN2) and a second input terminal of the op-amp OP1, and the resistor RA4 is coupled between the second input terminal of the op-amp OP1 and a second feedback terminal (for receiving the feedback signal FB2).

In another embodiment, the vent controller and the audio amplifier may further be combined, to generate an output signal which is a combination of the DC driving voltage and the AC audio signal. For example, the voltage generator or bias generator for generating the DC driving voltages VD1 and VD2 may be omitted, and the reference voltage of the audio amplifier may be well designed to control the DC level of the audio signal output by the audio amplifier to be at a desired value, so as to control the state of the vent.

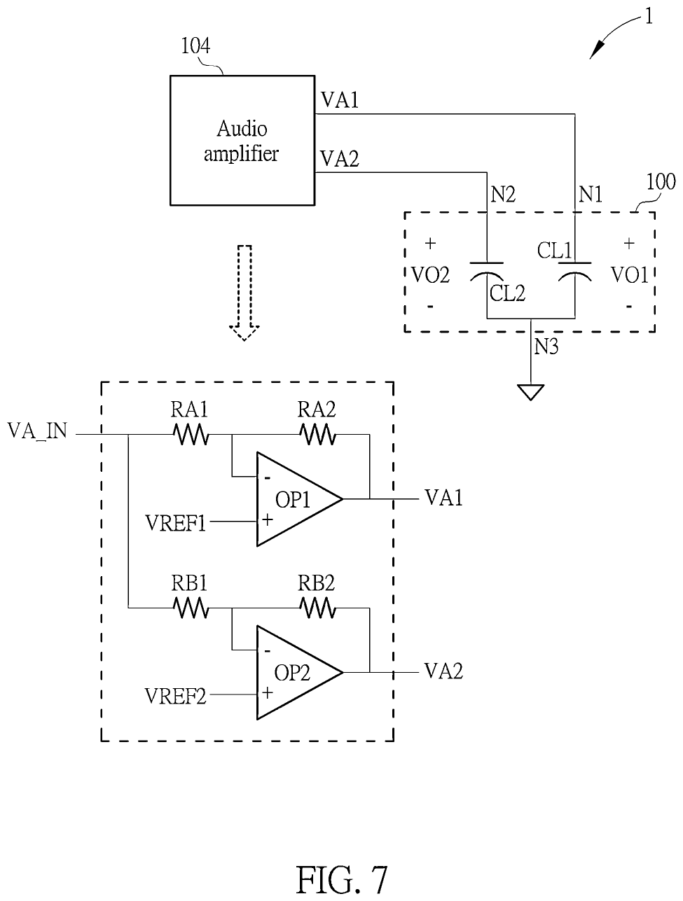

FIG. 7 is a schematic diagram of a detailed implementation of the audio control system 1 with a direct drive scheme. The direct drive scheme allows the audio amplifier 104 to directly drive the sound producing device 100 without using another voltage generator or bias generator such as the vent controller 102 shown in FIGS. 3-6. In another perspective, a voltage generator may be used to provide reference voltages VREF1 and VREF2 for the audio amplifier 104, to replace the vent controller 102 that outputs the driving voltages VD1 and VD2 to the sound producing device 100; hence, the audio amplifier 104 may generate audio signals VA1 and VA2 which are carried on the reference voltages VREF1 and VREF2, respectively.

In other words, the audio amplifier 104 in FIG. 7 is able to drive the sound producing device 100 to produce (audio) sound, and also to form the vent.

In this embodiment, since the audio signals VA1 and VA2 output by the audio amplifier 104 are already on their target DC levels, no coupling capacitor is needed in the audio control system 1. The audio amplifier 104 may directly output the audio signals VA1 and VA2 to the first flap and the second flap of the sound producing device 100, respectively, without through any coupling capacitor. The reference voltages VREF1 and VREF2 may have the same or different values, allowing the audio signals VA1 and VA2 to actuate the first flap and the second flap to reach the same or different positions, in order to control the state of the vent. Therefore, each of the audio signals VA1 and VA2 may include a DC component for controlling the displacement of the flap pair, and include an AC component for driving the sound producing device 100 to produce sound. The DC component comes from the reference voltage VREF1 or VREF2. The AC component comes from the audio input signal VA_IN.

FIG. 7 illustrates that the audio control system 1 is operated in the single-ended mode, where the audio amplifier 104 generates the audio signals VA1 and VA2 by receiving one audio input signal VA_IN. In detail, the audio amplifier 104 may include an op-amp OP1 and two resistors RA1 and RA2 (i.e., the first resistor and the second resistor), which are implemented and operated as in the above embodiments to generate the audio signal VA1 (i.e., the first audio signal). The audio amplifier 104 may further include an op-amp OP2 and two resistors RB1 and RB2 (i.e., the third resistor and the fourth resistor), which are coupled and operated in the same manner to generate the audio signal VA2 (i.e., the second audio signal).

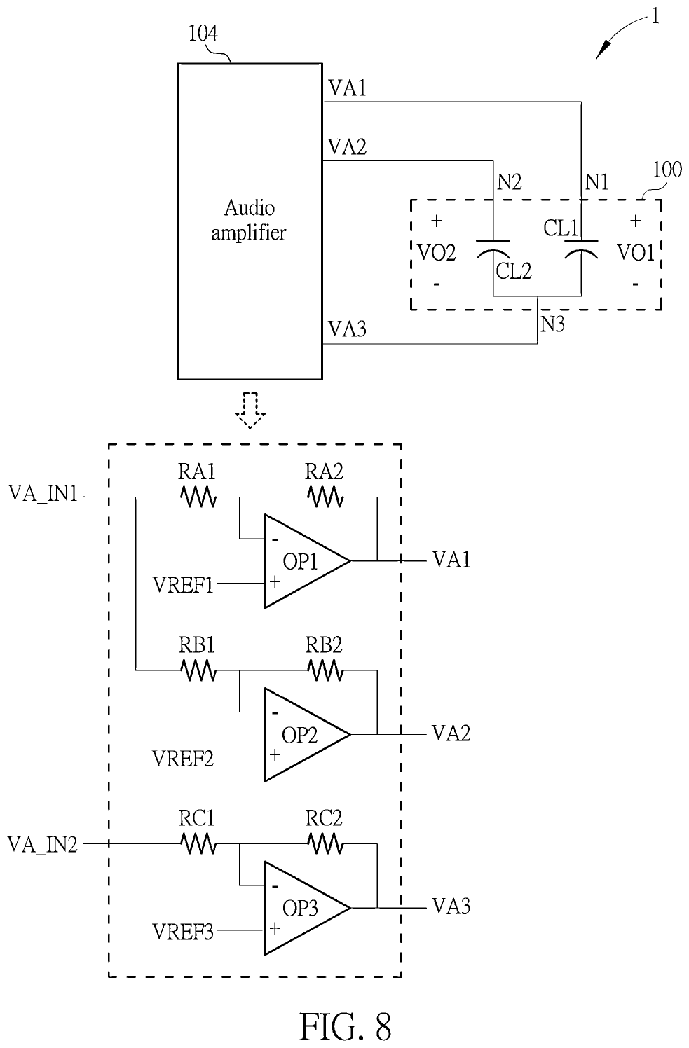

FIG. 8 is a schematic diagram of another detailed implementation of the audio control system 1 with the direct drive scheme. The circuit structure of the audio control system 1 shown in FIG. 8 is similar to that shown in FIG. 7, so signals and elements having similar functions are denoted by the same symbols. Similarly, the audio amplifier 104 in FIG. 8 is also able to drive the sound producing device 100 to produce (audio) sound and form the vent. Their difference is that the audio control system 1 shown in FIG. 8 is operated in a differential mode, and thus the audio amplifier 104 is configured to receive a differential audio input signal VA_IN1 and VA_IN2 to generate and output a differential audio signal VA1 and VA2 to the sound producing device 100.

In such a situation, the audio amplifier 104 should be well designed to realize the operations of the differential mode. In detail, the audio amplifier 104 includes three op-amps OP1-OP3 and six resistors RA1-RA2, RB1-RB2 and RC1-RC2. The op-amp OP1 is configured to generate the audio signal VA1 for the first flap by receiving the audio input signal VA_IN1 and the reference voltage VREF1, and the op-amp OP2 is configured to generate the audio signal VA2 for the second flap by receiving the audio input signal VA_IN1 and the reference voltage VREF2. The implementations and operations of the op-amps OP1-OP2 and the related resistors RA1-RA2 and RB1-RB2 are similar to those shown in FIG. 7, and will not be repeated herein. The op-amp OP3 and the resistors RC1-RC2 have a similar structure, so that the op-amp OP3 is configured to generate the audio signal VA3 to be output to the negative terminal of the flap pair (i.e., the node N3) by receiving the audio input signal VA_IN2 and a reference voltage VREF3.

Therefore, the audio signals VA1-VA3 may include a DC component for controlling the displacement of the flap pair, and include an AC component for driving the sound producing device 100 to produce sound. The DC component comes from the reference voltages VREF1-VREF3. The AC component comes from the differential audio input signals VA_IN1 and VA_IN2. The audio signals VA1-VA3 are output to the three terminals of the sound producing device 100, respectively, so as to drive the flap pair with differential signals.

In short, the device comprising the flap pair owns functions of both sound producing and vent forming, which relies on the controller of the present invention.

To sum up, the present invention provides a controller for a sound producing device to form a vent in the sound producing device and dynamically control the vent. The sound producing device may receive a driving signal which has a DC component and an AC component. The DC component may actuate the flap pair of the sound producing device to have a larger displacement to achieve different vent states. The AC component may be an audio signal for controlling the membrane to vibrate to produce sound. As a result, the dynamic vent control function and sound producing function may be integrated in the same controller.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A controller for controlling a sound producing device, the controller comprising:
a vent controller, configured to output a first driving voltage and a second driving voltage to the sound producing device, to control the sound producing device to form a vent; and
an audio amplifier, configured to output a first audio signal to the sound producing device, to produce a sound;
wherein the sound producing device comprises a flap pair, and the flap pair comprises a first flap and a second flap;
wherein the vent controller outputs the first driving voltage and actuates the first flap to generate a first displacement, the vent controller outputs the second driving voltage and actuates the second flap to generate a second displacement, and the vent is formed because of a difference between the first displacement and the second displacement.

2. The controller of claim 1, further comprising:
a first resistor, coupled between a first output terminal of the vent controller and the first flap; and
a second resistor, coupled between a second output terminal of the vent controller and the second flap.

3. The controller of claim 1, further comprising:
a first coupling capacitor, coupled between a first output terminal of the audio amplifier and a first terminal of the first flap of the sound producing device; and
a second coupling capacitor, coupled between the first output terminal of the audio amplifier and a first terminal of the second flap of the sound producing device.

4. The controller of claim 3, wherein a capacitance of each of the first coupling capacitor and the second coupling capacitor is greater than a capacitive load of the sound producing device.

5. The controller of claim 3, wherein the first audio signal is coupled to the first flap through the first coupling capacitor, and the first audio signal is coupled to the second flap through the second coupling capacitor.

6. The controller of claim 3, further comprising:
a third coupling capacitor, coupled between a second output terminal of the audio amplifier and a second terminal of the first flap and a second terminal of the second flap.

7. The controller of claim 6, wherein the second terminal of the first flap is connected to the second terminal of the second flap.

8. The controller of claim 6, wherein the first audio signal is coupled to the first terminal of the first flap through the first coupling capacitor, the first audio signal is coupled to the first terminal of the second flap through the second coupling capacitor, and a second audio signal is coupled to the second terminal of the first flap and the second terminal of the second flap through the third coupling capacitor.

9. The controller of claim 3, further comprising:
a first feedback capacitor, coupled between a first feedback terminal of the audio amplifier and the first terminal of the first flap; and
a second feedback capacitor, coupled between the first feedback terminal of the audio amplifier and the first terminal of the second flap.

10. The controller of claim 9, wherein the audio amplifier is configured to receive a feedback signal from the flap pair through the first feedback capacitor and the second feedback capacitor.

11. The controller of claim 9, further comprising:
a third feedback capacitor, coupled between a second feedback terminal of the audio amplifier and a second terminal of the first flap and a second terminal of the second flap.

12. The controller of claim 11, wherein the audio amplifier is configured to receive a first feedback signal from the flap pair through the first feedback capacitor and the second feedback capacitor, and receive a second feedback signal from the flap pair through the third feedback capacitor.

13. The controller of claim 1, wherein the audio amplifier comprises a single-ended amplifier, which is configured to output the first audio signal to a first terminal of the first flap and a first terminal of the second flap.

14. The controller of claim 13, wherein the single-ended amplifier comprises:
an operational amplifier, having a first input terminal, a second input terminal and an output terminal;
a first resistor, coupled between an audio input terminal and the second input terminal of the operational amplifier; and
a second resistor, coupled between the second input terminal of the operational amplifier and the output terminal of the operational amplifier.

15. The controller of claim 14, wherein the audio input terminal is configured to receive an audio input signal, and the first input terminal of the operational amplifier is configured to receive a reference voltage.

16. The controller of claim 13, wherein the single-ended amplifier comprises:
an operational amplifier, having a first input terminal, a second input terminal and an output terminal;
a first resistor, coupled between an audio input terminal and the second input terminal of the operational amplifier; and
a second resistor, coupled between the second input terminal of the operational amplifier and a feedback terminal.

17. The controller of claim 16, wherein the audio input terminal is configured to receive an audio input signal, the first input terminal of the operational amplifier is configured to receive a reference voltage, and the feedback terminal is configured to receive a feedback signal from the flap pair.

18. The controller of claim 1, wherein the audio amplifier comprises a differential amplifier, which is configured to output the first audio signal to a first terminal the first flap and a first terminal of the second flap and output a second audio signal to a second terminal of the first flap and a second terminal of the second flap.

19. The controller of claim 18, wherein the differential amplifier comprises:
an operational amplifier, having a first input terminal, a second input terminal, a first output terminal and a second output terminal;
a first resistor, coupled between a first audio input terminal and the first input terminal of the operational amplifier;
a second resistor, coupled between the first input terminal of the operational amplifier and the first output terminal of the operational amplifier;
a third resistor, coupled between a second audio input terminal and the second input terminal of the operational amplifier; and
a fourth resistor, coupled between the second input terminal of the operational amplifier and the second output terminal of the operational amplifier.

20. The controller of claim 19, wherein the first audio input terminal and the second audio input terminal are configured to receive a differential audio input signal.

21. The controller of claim 18, wherein the differential amplifier comprises:
an operational amplifier, having a first input terminal, a second input terminal, a first output terminal and a second output terminal;
a first resistor, coupled between a first audio input terminal and the first input terminal of the operational amplifier;
a second resistor, coupled between the first input terminal of the operational amplifier and a first feedback terminal;
a third resistor, coupled between a second audio input terminal and the second input terminal of the operational amplifier; and
a fourth resistor, coupled between the second input terminal of the operational amplifier and a second feedback terminal.

22. The controller of claim 21, wherein the first audio input terminal and the second audio input terminal are configured to receive a differential audio input signal, the first feedback terminal is configured to receive a first feedback signal from the flap pair, and the second feedback terminal is configured to receive a second feedback signal from the flap pair.

23. The controller of claim 1, wherein the difference between the first displacement and the second displacement is greater than a thickness of the flap pair.

24. The controller of claim 1, wherein the first driving voltage actuates the first flap to move toward a first direction and the second driving voltage actuates the second flap to move toward a second direction opposite to the first direction, to control the flap pair to form the vent.

25. A controller for controlling a sound producing device, the controller comprising:
an audio amplifier, configured to drive the sound producing device to form a vent and to produce a sound;
wherein the sound producing device comprises a flap pair, and the flap pair comprises a first flap and a second flap;
wherein the audio amplifier actuates the first flap to generate a first displacement, the audio amplifier actuates the second flap to generate a second displacement, and the vent is formed because of a difference between the first displacement and the second displacement.

26. The controller of claim 25, wherein the audio amplifier comprises:
a first operational amplifier, having a first input terminal, a second input terminal and an output terminal;
a first resistor, coupled between an audio input terminal and the second input terminal of the first operational amplifier;
a second resistor, coupled between the second input terminal of the first operational amplifier and the output terminal of the first operational amplifier;
a second operational amplifier, having a first input terminal, a second input terminal and an output terminal;
a third resistor, coupled between the audio input terminal and the second input terminal of the second operational amplifier; and
a fourth resistor, coupled between the second input terminal of the second operational amplifier and the output terminal of the second operational amplifier.

27. The controller of claim 26, wherein the audio input terminal is configured to receive an audio input signal, the first input terminal of the first operational amplifier is configured to receive a first reference voltage, and the first input terminal of the second operational amplifier is configured to receive a second reference voltage.

28. The controller of claim 26, wherein the first operational amplifier is configured to output a first audio signal, and the second operational amplifier is configured to output a second audio signal.

29. The controller of claim 25, wherein a first audio signal is output to a first terminal of the first flap and a second audio signal is output to a first terminal of the second flap, and the audio amplifier is further configured to output a third audio signal to a second terminal of the first flap and a second terminal of the second flap.

30. The controller of claim 29, wherein the audio amplifier comprises:
a first operational amplifier, having a first input terminal, a second input terminal and an output terminal;
a first resistor, coupled between a first audio input terminal and the second input terminal of the first operational amplifier;
a second resistor, coupled between the second input terminal of the first operational amplifier and the output terminal of the first operational amplifier;
a second operational amplifier, having a first input terminal, a second input terminal and an output terminal;
a third resistor, coupled between the first audio input terminal and the second input terminal of the second operational amplifier;
a fourth resistor, coupled between the second input terminal of the second operational amplifier and the output terminal of the second operational amplifier;
a third operational amplifier, having a first input terminal, a second input terminal and an output terminal;
a fifth resistor, coupled between a second audio input terminal and the second input terminal of the third operational amplifier; and
a sixth resistor, coupled between the second input terminal of the third operational amplifier and the output terminal of the third operational amplifier.

31. The controller of claim 30, wherein the first audio input terminal and the second audio input terminal are configured to receive a differential audio input signal, the first input terminal of the first operational amplifier is configured to receive a first reference voltage, the first input terminal of the second operational amplifier is configured to receive a second reference voltage, and the first input terminal of the third operational amplifier is configured to receive a third reference voltage.

32. The controller of claim 30, wherein the first operational amplifier is configured to output the first audio signal, the second operational amplifier is configured to output the second audio signal, and the third operational amplifier is configured to output the third audio signal.

33. The controller of claim 25, wherein the difference between the first displacement and the second displacement is greater than a thickness of the flap pair.

34. The controller of claim 25, wherein the first reference voltage actuates the first flap to move toward a first direction and the second reference voltage actuates the second flap to move toward a second direction opposite to the first direction, to control the flap pair to form the vent.

35. The controller of claim 25,
wherein the audio amplifier receives a first reference voltage and a second reference voltage;
wherein the audio amplifier actuates the first flap to generate the first displacement according to the first reference voltage, and actuates the second flap to generate the second displacement according to the second reference voltage.
